(19) United States
(12) Patent Application Publication
(10) Pub. No.: US 2010/0144080 A1
(43) Pub. Date: Jun. 10, 2010

(54) METHOD AND APPARATUS TO TRANSFER COAT UNEVEN SURFACE

(75) Inventor: Rob Qing Yuan Ong, Santa Clara, CA (US)

Correspondence Address: HULSEY IP INTELLECTUAL PROPERTY LAWYERS, P.C., 919 Congress Avenue, Suite 919, AUSTIN, TX, 78701, US

(73) Assignee: Solexel, Inc.

(21) Appl. No.: 12/620,162

(22) Filed: Nov. 17, 2009

Related U.S. Application Data
(63) Continuation-in-part of application No. 12/477,094, filed on Jun. 2, 2009, now abandoned.
(60) Provisional application No. 61/195,620, filed on Jun. 2, 2008.

(51) Int. Cl. H01L 31/18

(52) U.S. Cl. 438/57; 118/58; 257/E31.001

(57) ABSTRACT

A method and apparatus for transferring material on at least a portion of an uneven surface of a substrate in the manufacture of photovoltaic cells, which may include, but is not limited to a thin-film solar substrates (3-D TFSS). An apparatus for transfer coating onto an uneven surface comprising an applicator roll, a transport roll, a heating device, a drying system, a conveying system, a reservoir, a blade, and a substrate. A method for positioning a substrate, selectively coating the material on an uneven surface, compressing the material to conform at the uneven surface, heating the material to a temperature more than that of the substrate, and drying the material to form continuous material coverage on said uneven surface. A method and apparatus for passing the substrate in a controlled environment, agitating the material prior to step of selectively coating, and heating the conveying plane.

### CROSS-REFERENCE TO RELATED APPLICATIONS

This U.S. patent application is a continuation-in-part of pending U.S. patent application Ser. No. 12/477,094 filed Jun. 2, 2009 entitled, “METHOD AND APPARATUS TO TRANSFER COAT UNEVEN SURFACE” by inventor Rob (Qing Yuan) Ong, which claims the benefit of priority of U.S. Provisional Patent Application No. 61/195,620, filed Jun. 2, 2008, entitled, “METHOD AND APPARATUS TO TRANSFER COAT UNEVEN SURFACE” by inventor Rob (Qing Yuan) Ong, which is incorporated herein by reference in its entirety.

### FIELD

This disclosure relates in general to the field of methods for coating three-dimensional thin-film solar substrates (3-D TFSS), and more particularly, the presently disclosed subject matter relates to methods and apparatus to transfer coat uneven surfaces, and even more particularly to methods and apparatus for selectively coating.

### DESCRIPTION OF THE RELATED ART

Substantial literature exists describing the manufacture of thin-film photovoltaic devices. One or more coatings may be applied in layers directly on the surface of photovoltaic cells. Coating is the process by which liquid layers may be applied to the surface of a solid, and is a process of dynamic wetting of a web. Several layers of coating material may be applied simultaneously to a moving web, but there may be a risk of imperfections. A coating method and apparatus may serve three primary functions: 1) conveyance of a web, which may be, but is not limited for being selectively coated; 2) application of the liquid layers to the web; and 3) removal of the volatile components.

It is often desirable to form a thin layer of film from a liquid coating material on the top surfaces or ridges of three dimensional microstructures on a substrate, which may include, but is not limited to, three-dimensional thin-film solar substrates (3-D TFSS). An example of such a substrate is a honeycomb-prism silicon substrate with hexagonal-prism sidewalls or a silicon substrate with square or octagonal apertures. Applications of such substrates may include photovoltaic cells (such as three-dimensional thin-film cells), micro-electro-mechanical systems (MEMS), and other semiconductor microelectronic microstructures, which may include, but are not limited to having raised features.

Additionally, it may be advantageous to coat the top surfaces or top ridges (i.e. top surfaces with wraparound on sidewalls) of an uneven surface of a 3-D TFSS with desired transferred material. The unevenness could be created by but not limited to etching, micro-machining, micro-molding, drilling, laser ablation, shadow-mask deposition, etc.

Coating material such as, but not limited to, spin-on dopant is typically distributed in low viscosity alcohol based liquid forms and its stability is determined by how long it remains a liquid. When it starts to gel or solidify, manufacturers typically consider this a detrimental change because the material is no longer usable for spin-coating applications. Typically, the material is only used to the point when it starts to gel or solidify and do not attempt to understand the subsequent dopant characteristics. Manufacturers often attempt to slow down this process by storing the material at low temperatures.

A major limitation of coating a 3-D TFSS is the ability to coat the ridges while minimizing the amount of coating along the sidewalls and inside the wells.

A further limitation of coating a 3-D TFSS is to permit the liquid to flow down the sidewalls while preventing the liquid from dripping to the bottom of the structure.

Thus, a need exists, therefore, for selectively coating the ridges of a 3-D TFSS.

A further need exists for preventing surface tension effects and capillary actions from drawing coated liquid along the sidewalls and inside the wells of a 3-D TFSS.

Yet, a further need exists for controlling the amount of liquid that needs to be transferred in the coating of a 3-D TFSS.

Moreover, a need exists to control the quality of coverage, whether it be spotty or uniform in nature of a 3-D TFSS.

Further, a need exists to control the quality of the final film thickness of the coating of a 3-D TFSS.

Finally, a need exists to prevent patterns, such as streaks, from forming of a 3-D TFSS.

### SUMMARY

The following description is not to be taken in a limiting sense, but is made for the purpose of describing the general principles of the present disclosure. The scope of the present disclosure should be determined with reference to the claims. And although described with reference to the coating of three-dimensional thin-film solar substrates (3-D TFSS), a person skilled in the art could apply the principles discussed herein to the coating of any multi-dimensional substrate or uneven surface.

A method and apparatus for transferring material on at least a portion of an uneven surface of a substrate in the manufacture of photovoltaic cells or solar cells, which may include, but is not limited to a 3-D TFSS. More concretely and with the example of improved coated ridge of an uneven surface with a desired transferred material: An apparatus for transfer coating onto an uneven surface comprising an applicator roll, a transport roll, a heating device, a drying system, a conveying system, a reservoir, a blade, and a substrate. The present disclosure teaches a method for positioning a substrate, selectively coating the material on an uneven surface, compressing the material to conform at the uneven surface, heating the material to a temperature more than that of the substrate, and drying the material to form continuous material coverage on said uneven surface. In another aspect, a method and apparatus for passing the substrate in a controlled environment, agitating the material prior to step of selectively coating, and heating the conveying plane. These improvements, either singly or jointly, may thus include at least eighty percent continuous material coverage on the ridges, no more than one-hundred microns film thickness on the ridges, no more than either one-hundred microns thickness of sidewall coverage, and no more than one-hundred microns thickness of wells coverage or thirty percent of the aperture opening (whichever is larger).

Other advantages of the disclosed subject matter, as well as additional novel features, will be apparent from the description provided herein. The intent of this summary is not to be a comprehensive description of the claimed subject matter, but rather to provide a short overview of some of the subject matter's functionality. Other systems, methods, features and advantages here provided will become apparent to one with skill in the art upon examination of the following FIGURES and detailed description. It is intended that all such additional systems, methods, features and advantages be included within this description, be within the scope of the accompanying claims.

### BRIEF DESCRIPTIONS OF THE DRAWINGS

The present subject matter will now be described in detail with reference to the drawings, which are provided as illustrative examples of the subject matter so as to better enable those skilled in the art to practice the subject matter. Notably, the figures and examples are not meant to limit the scope of the present subject matter to a single embodiment, but other embodiments are possible by way of interchange of some or all of the described or illustrated elements and, further, wherein:

FIG. 1 shows a coating layout for the coating of three-dimensional thin-film solar substrates (3-D TFSS).

FIG. 2 illustrates an exemplary microcoater for transfer coating onto an uneven surface.

FIG. 3 presents an integrated coating system for the coating of a 3-D TFSS.

FIG. 4 displays an exemplary microcoater and an exemplary recirculation-pump-filtration unit.

FIG. 5 depicts a gelation process that may be implemented in the manufacture of a solar cell, which may be associated with a 3D-TFSS.

FIG. 6 portrays an exemplary microscope view of a coated profile of a honeycomb structure of a 3-D TFSS.

FIG. 7 provides a different exemplary microscope view coated profile of a honeycomb structure of a 3-D TFSS.

FIG. 8 shows an exemplary microscope view metal coated profile of a honeycomb structure of a 3-D TFSS.

FIG. 9 illustrates a microscope view of a coated profile of pyramid cell.

FIG. 10 presents a thicker coated profile along sidewall of honeycomb cell.

FIG. 11 displays a thinner coated profile along sidewall of honeycomb cell.

FIG. 12 depicts a coated profile of the top ridge of a honeycomb cell.

### DETAILED DESCRIPTION OF THE INVENTION

In the present specification, an embodiment showing a singular component should not be considered limiting. Rather, the subject matter encompasses other embodiments including a plurality of the same component, and vice-versa, unless explicitly stated otherwise herein. Moreover, applicants do not intend for any term in the specification or claims to be ascribed an uncommon or special meaning unless explicitly set forth as such. Further, the present subject matter encompasses present and future known equivalents to the known components referred to herein by way of illustration.

In describing embodiments of the present invention illustrated in the drawings, specific terminology is employed for the sake of clarity.

The present disclosure teaches a method and apparatus to coat the top surfaces or top ridges, which may be the top surfaces with wraparound on sidewall, of an uneven surface with desired transferred material for the manufacture of photovoltaic cells, which may include, but is not limited to a thin-film solar substrate (3-D TFSS). The unevenness could be created by, but not limited to, etching, micro-machining, micro-molding, drilling, laser ablation, shadow-mask deposition, etc.

An “uneven surface” may be defined as combination of ridges and wells along the surface of a three-dimensional thin-film solar substrate (3-D TFSS). More particularly, “wells” may be associated with a 3-D TFSS' bottom portion that supports the “ridges”. The “ridges” may be associated with a 3-D TFSS' raised portions that are supports the “wells” below. Further, the tips of any apertures on the uneven surface of a 3-D TFSS may be less than or equal to four millimeters width in terms of the longest dimension. A “sidewall” may refer to the structures in a 3-D TFSS that provides structural support to any raised surface from the lowest point to the top point or any ridges of a 3-D TFSS.

The present disclosure significantly improves the coated ridge of an uneven surface with a desired transferred material, which may include, but is not limited to the following desirable characteristics: 1) at least eighty percent continuous coverage on any raised surface from the lowest point to the top point or any or on any ridge; 2) good surface area coverage, which may include at least ninety percent continuous material coverage on the ridges; (3) relatively small coverage area along the sidewalls with minimal depth, which may be no more than one-hundred microns thickness of sidewall coverage; (4) little to no material at the bottom of the holes, which may be no more than one-hundred microns thickness of wells coverage; and (5) thin layer of film, which may be less than one micron in thickness.

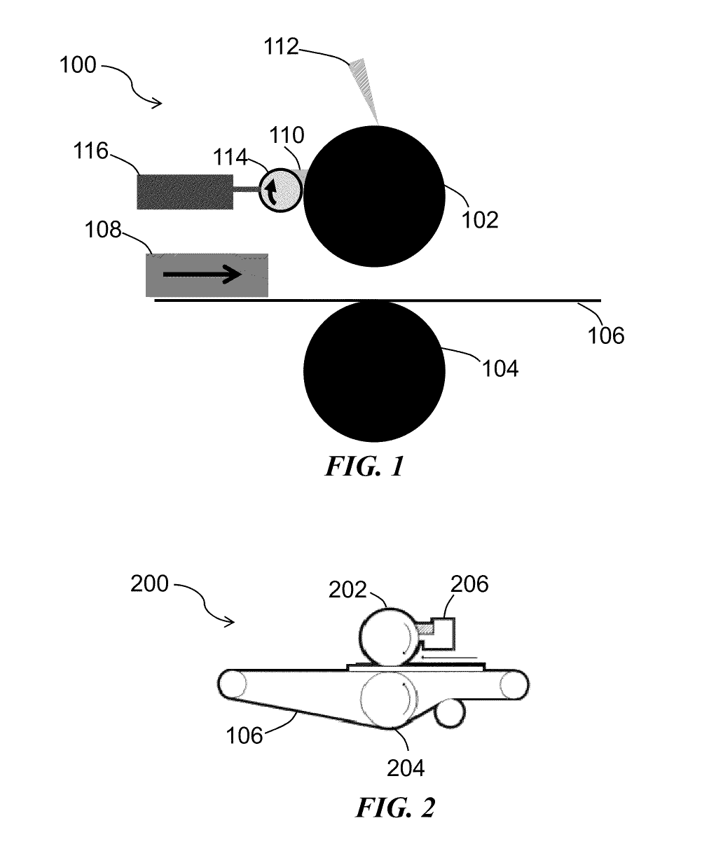

FIG. 1 shows a coating layout 100, which may be, but is not limited to, a reverse roll system, for the coating of a 3-D TFSS. The coating layout 100 may be comprised of subcomponents, which may include, but is not limited to, an applicator roll 102, a transport roll 104, a conveyance plane 106, a wafer 108, coating material 110, a cleaning blade 112, a dosing roll 114, and a pneumatic 116. Various modifications to these coating layout embodiments and coating configurations may exist. Furthermore, alternate commercial coating systems may be implemented to achieve the presently disclosed subject matter.

More particularly, the conveyance plane 106 may be, but is not limited to, a belt, a roll-to-roll plane, a walking beam transport, or carriers that move from start to end and then get recirculated after going through cleaning steps among others.

In one embodiment of the present disclosure, the coating material 110 is a dopant. However, the coating material 110 may be, but is not limited to being an emulsion, a solvent (that may contain dispersed particles), a gel, a sol-gel, a wax, a paste (that may be or already pre-coated on a another transfer surface, such as tape), an adhesive, a powder (that may have particle sizes ranging from nanometers to several micron dimensions), an ink, a glue, a photosensitive material, a dopant (such as phosphorous and boron), a metal-organic liquid metal (such as aluminum and silver), a resist, an etch paste (such as an acidic one), and polymers (such as silicone). Further, the coating material 110 may be comprised of subcomponents that each have a different viscosity, volatility, flammability, stability, acidity, color, wetability, etc. Further, the conveyance plane 106 may be, but is not limited to, a belt, walking beam, roll-to-roll, carrier chucks, and vacuum transport table. Further, the coating layout 100 may occur in a controlled environment saturated with certain solvents, temperature, humidity, and wind control.

Further, the coating material 110 may be associated with liquid or paste materials that may be capable of being coated on the tips of any apertures that may be less than or equal to four millimeters width in terms of longest dimension. Further, the coating material 110 may be associated with liquid or paste materials that may be capable of being coated without excessive side coverage, which may be defined as one-hundred micron or thirty percent of the aperture size, whichever may be larger.

The wafer 108 may have a substrate that may include, but is not limited to, the following characteristics. The shape of the wafer 108 may be, but is not limited to being, circular or rectangular, hexagon as panels. The size of the wafer 108 may be, but is not limited to being, a few inches to a few feet. The thickness of the wafer 108 may be, but is not limited to being tens of microns to several millimeters to varying throughout the substrate. The structure depth of the wafer 108 may be, but is not limited to being, tens of microns to several millimeters, varying throughout the substrate. The percentage of the remaining top area of the wafer 108 may be, but is not limited to being, from less than ten percentage to greater than ninety percentage, varying throughout the substrate. The material of the wafer 108 may be, but is not limited to being, semiconductor materials such as silicon, ceramic, metal, polymers, glass, plastics, or a thin film material, which may be but is not limited to, oxide, nitride, a chemical surface treatment for improving wetting, adhesion, color, etc.

In the coating layout 100, the wafer 108 may move from the right to the left on the conveyance plane 106. Further, in the coating layout 100, the wafer 108 may be stationary and the coating head may be moved on the piece that needs to be coated. The coating layout 100 may depend on the transport system used. The transport roll 104 may rotate, thereby causing the movement of the conveyance plane 106 and resulting in the movement of the wafer 108 on the conveyance plane 106. During the process of coating a 3-D TFSS, the pneumatic 116 may provide electrical energy input to the dosing roll 114, thereby mechanically-rotating the dosing roll 114 and compressing the dosing 114 against other rollers/surfaces. The rotation of the dosing roll 114 may permit mechanical rotation of the applicator roll 102, which may apply the coating material 110 to the applicator roll 102. Further, the speeds of the various rollers and belts may not be the same, but instead they may be all different. The cleaning blade 112 may prevent inadequate build-up of coating material 110 on the applicator roll 102, thereby creating a thin and uniform layer of coating material 110 on the applicator roll 102. While the wafer 108 may be moving on the conveyance plane 106, the applicator roll 102 may transfer the coating material onto wafer.

Further, the coating layout 100 may coat wafers on both sides simultaneously. In such a case, the transport system may feed the wafer 108 in and retrieve the wafer 108 from the other side since the moving rollers will move the wafer through.

Heating may occur on the conveyance plane 106, applicator roll 102, transport roll 104, and/or dosing roll 114. The process of heating may be applied to the coating material 110, which may make the coating material 110 thinner or may dry out the solvents and make transform the coating material 110 into a higher viscosity or higher solid content. Further, the process of heating may be accomplished by using infrared lamps, UV (not shown), conduction coils (not shown), a heating element (not shown), hot air oven (not shown), or other heating means (not shown).

Further, compression may occur between the surface of the conveying plane 106 and the coating material 110. More particularly, a roller surface may be used for evaporation, instead of heating, vacuum, air, etc.; in such a case, the coating material 110, which may be a dopant gel, may need to be “pressed” against the roller surface. Such a compression process may further thin the coating material 110. The material of choice for the applicator roll 102 may be a compressible material, so that the applicator roll 102 may conform to the different regions and uneven surfaces of the wafer 108. Further, the applicator roll 102 or the dosing roll 114 may not have a flat surface or may have microgrooves designed to hold fixed volumes. The microgrooves and microholes may be in the shape of, but not limited to, a diamond, square, or rectangular. Further the microgrooves and microholes may contain liquid for transferring from the dosing roll 114 to applicator roll 102 to control the film thickness independent of other factors. The dosing roll 114 and the applicator roll 102 might also have texturing, which may enable pattern printing; if they have texturing, it may be on the hard roller, which may then transfer to the soft roller for printing onto the wafer 108. The dosing roll 114 and the applicator roll 102 may have positive or negative patterns depending on the material properties and how it is to be coated.

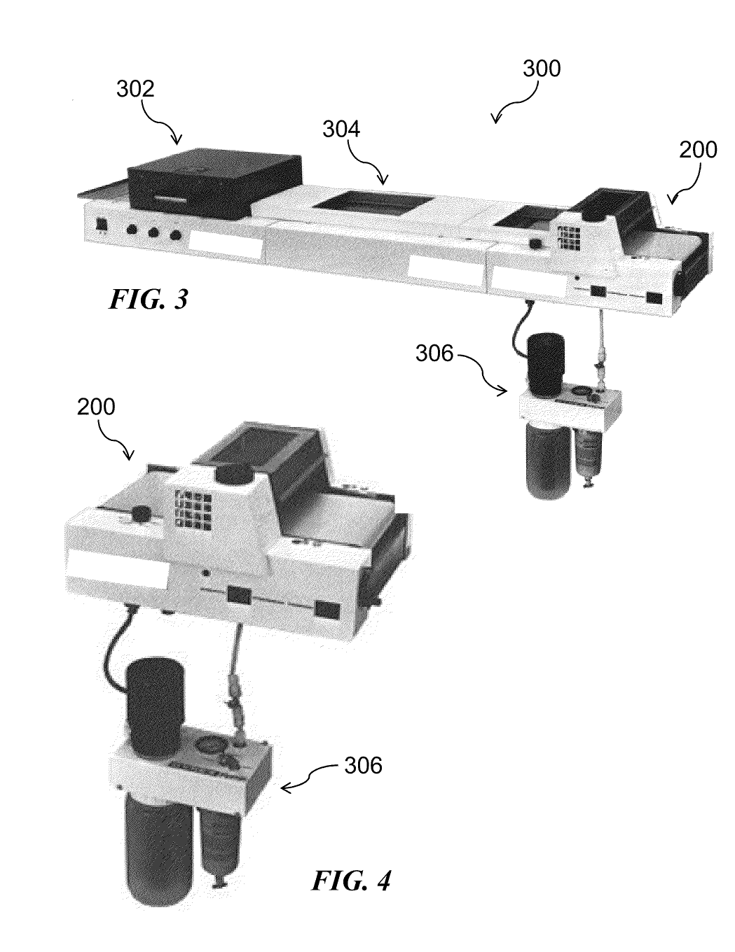

FIG. 2 illustrates an exemplary microcoater 200 for transfer coating onto an uneven surface. While FIG. 1 shows an embodiment of the presently disclosed subject matter, FIG. 2 and FIG. 3 portray alternative embodiments of the presently disclosed subject matter. More particularly, the disclosed subject matter as shown in FIG. 1, FIG. 2, and FIG. 3 describes a method and apparatus to coat a thin film of no more than one-hundred microns onto the ridges of a wafer 108.

In an alternative embodiment for the coating of a 3-D TFSS, the coating layout 100 may be comprised of a threaded coating roll 202, an adjustable coating roll 204, and a doctor blade 206. The threaded coating roll 202 may have a similar function as an applicator roll 102, which may apply the coating material 110 to it. Further, the threaded coating roll 202 may transfer the coating material onto wafer 108. Further, the adjustable coating roll 204 may have a similar function as a transport roll 104; the rotation of the adjustable coating roll 204 may cause the movement of the conveyance plane 106, thereby resulting in the movement of the wafer 108 on the conveyance plane 106. Further, the doctor blade doctor blade 206 may have a similar function as a cleaning blade 112; the doctor blade 206 may prevent inadequate build-up of coating material 110 on the threaded coating roll 202, thereby creating a thin and uniform layer of coating material 110 on the threaded coating roll 202. Further, heating may occur on the threaded coating roll 202 and adjustable coating roll 204.

With reference to FIGS. 1 and 2, the method and apparatus of selectively coating may be associated with at least one of the following: roll coating; angled spray coating; tampon printing; spin coating; direct diffusion; powder coating; nanocontact printing; ligand functionalization; stamp coating; and thin film deposition. Further, selective coating may refer to only coats the areas contacting the coating material but leaving the uncontacted area as not being coated. For each of the previous listed methods, there may exist different application equipment. Additionally, direct diffusion with a doped rubber stamp or pre-coat with an alternative material may assist in binding the target transfer material, thereby increasing surface tension, which may be associated with, but is not limited to, dopant surface tension.

FIG. 3 presents an integrated coating system 300 for the coating of a 3-D TFSS. Integrated coating system 300 may be modified to control the amount of coating material 110 that may transferred during the coating process, to control the amount of coating material 110 on the side walls and the wells, and to control the amount and thinness of coating material that may be applied to the uneven surfaces of the wafer 108.

The integrated coating system 300 may include, but is not limited to, a microcoater 200, a microdryer 302, a leveling conveyor 304, and a recirculation-pump-filtration unit 306. The leveling conveyor 304 may move the conveyance plane 106, thereby transporting the wafer 108 during the coating process. The microdryer 302 may further heat the coating material 110 and/or may remove of the volatile components of coating material 110. However, a drying device other than a microdryer 302 may perform post coat drying via vacuum bake, air gun, etc. The microdryer 302, which may be, but is not limited to being, a vacuum oven may be used to pre-heat wafers which are manually transferred to the integrated coating system 300, and back for bakes with or without vacuum. The recirculation-pump-filtration unit 306 may recirculate, pump, and/or filter the coating material 110 during the process of coating a 3-D TFSS.

The present disclosure teaches a method and apparatus to transfer coat uneven surface and achieve desired coverage on top surface and/or ridges with an integrated coating system 300. The pressure may be the most important factors for controlling the coating. Other factors that may be important include, but are not limited to: the direction that the wafer 108 was loaded; the amount of compression; the presence of vacuum bake; the choice of wafer orientation, with respect to facing upward or downward during bake; the number of roller coats; the bake temperature; the relative speeds of rollers with respect to each other; the pressure between various rollers and surfaces; the speed of the conveyance plane 106; the wafer 108 loading direction, whether it is loaded edge first or point first; the position of the wafer 108 on the conveyance plane 106 relative to the vacuum holes; the rotating direction of the rollers; the placement of the wafer 108, whether the wafer 108 is placed on a carrier or directly onto the conveyance plane 106.

Further, key factors impacting gelation include, but are not limited to, the evaporation rate, temperature, agitation etc.

An integrated coating system 300 for the coating of a 3-D TFSS may be realized in a variety of ways. For example, an integrated coating system 300 might be configured with polyimide tape adhesive that is applied to the surface and heated at one-hundred fifteen degrees Celsius for several minutes before it may be peeled off gently without breaking the wafer to leave the residue. Additionally, an integrated coating system 300 might be configured to produce outputs. The following table portrays the outputs that may be associated with, but is not limited to, a soft stamp set-up, in which spin coating of the liquid onto a surface may be followed by pressing the 3-D TFSS against the surface for accomplishing the desired transfer coat:

| | Dilution | Bake Temp. | Bake Time | Thickness |
|---|---|---|---|---|
| Wafer # | (x:1) | (° C.) | (sec) | (rpm) |
| 4 | 0 | 105.9 | 30 | 3000 |
| 5 | 0 | 102.4 | 30 | 5000 |
| 6 | 1 | 109.7 | 30 | 3000 |

Furthermore, the disclosed subject matter of FIG. 1, FIG. 2, and FIG. 3 describes a method and apparatus to transfer coat an uneven surface with the use of rollers, either singly or jointly. More particularly, the disclosed subject matter of FIG. 1, FIG. 2, and FIG. 3 describes a method and apparatus to transfer coat an uneven surface to prevent sidewall coverage. Furthermore, the disclosed subject matter of FIG. 1, FIG. 2, and FIG. 3 describes a method and apparatus to coat no more than two-hundred microns in thickness. Furthermore, various modifications to these coating layout embodiments and coating configurations may achieve transfer coating of less than two-hundred microns thickness, which may be no more than one-hundred microns in thickness.

FIG. 4 displays a close-up view of an exemplary microcoater 200 and an exemplary recirculation-pump-filtration unit 306.

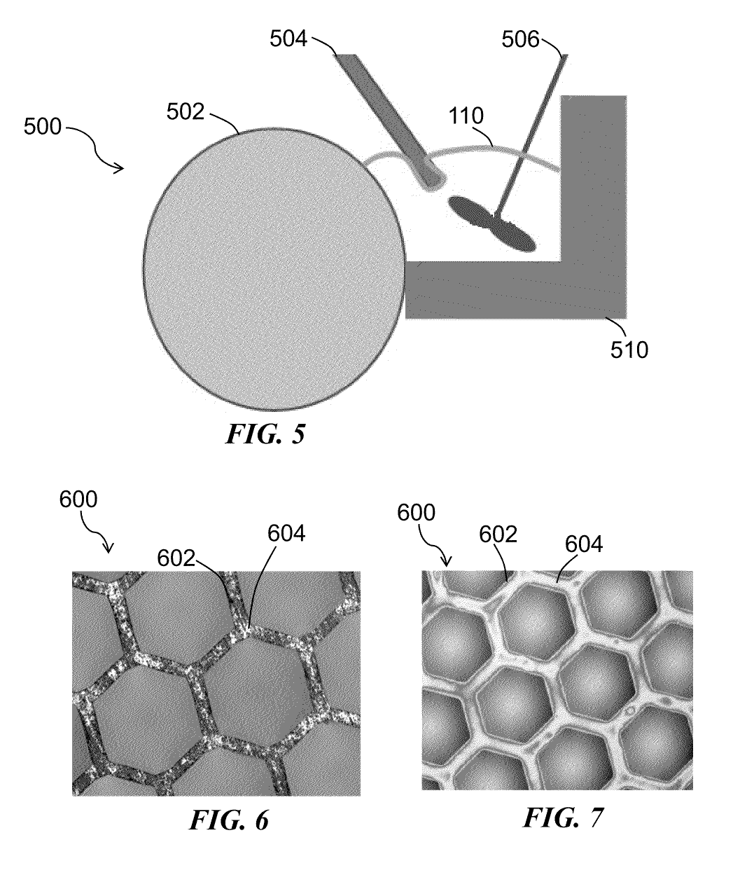

FIG. 5 depicts a gelation process layout 500 that may be implemented in the manufacture of a solar cell or may be associated with the manufacture of a 3-D TFSS. The gelation process layout 500 may create a more coatable liquid and may result in a longer shelf life for the coating material 110 on the 3-D TFSS. The gelation process layout 500 may include, but is not limited to, a roller 502, a pressing tool 504, an agitator 506, a coating material 110, and a doctor bar reservoir 510.

The coating material 110 may reside in the doctor bar reservoir 510 or in a separate dispenser that may be dispensed to match the volume being consumed and to maintain equilibrium so that the liquid does not evaporate, thicken over time, and affect the amount of material coated. The agitator 506 may agitate the coating material 110 with the use of a pressing tool 504. The agitation of the coating material 110 may permit an aging process in the coating material 110, which may allow for viscosities much greater than 50,000 centipose, which is the theoretical limit that may be permissible by chemical modification alone. The agitator 506 may increase the viscosity of the coating material 110 up to, but not limited to, 200,000 centipose.

The pressing tool 504 may press the coating material 110 onto the surface of the roller 502 in the gelation process layout 500. The gelation process may pull away the coating material 110, thereby increasing the surface area for solvent evaporation to aid in gelation.

FIG. 6 portrays an exemplary microscope view of a coated profile 600 of a honeycomb structure of a 3-D TFSS. The microscope view of a coated profile 600 shows the coated material 604 on the top ridge of the honeycomb structure 602. The present disclosure teaches a method and apparatus for coating an uneven surface of such a 3-D TFSS, wherein the top ridge of the honeycomb structure 602 is adequately coated.

FIG. 7 provides a different exemplary microscope view coated profile 600 of a honeycomb structure of a 3-D TFSS, which shows an alternative view of the coated material 604 on the top ridge of the honeycomb structure 602. One will note the good coverage obtained; however, from a much simpler process than previously. Here the wafer was at room temperature and a single coat of gel dopant was applied with only a final bake. The obtained coverage in this example is more uniform along the sidewalls than the above example and had depths up to 30 microns.

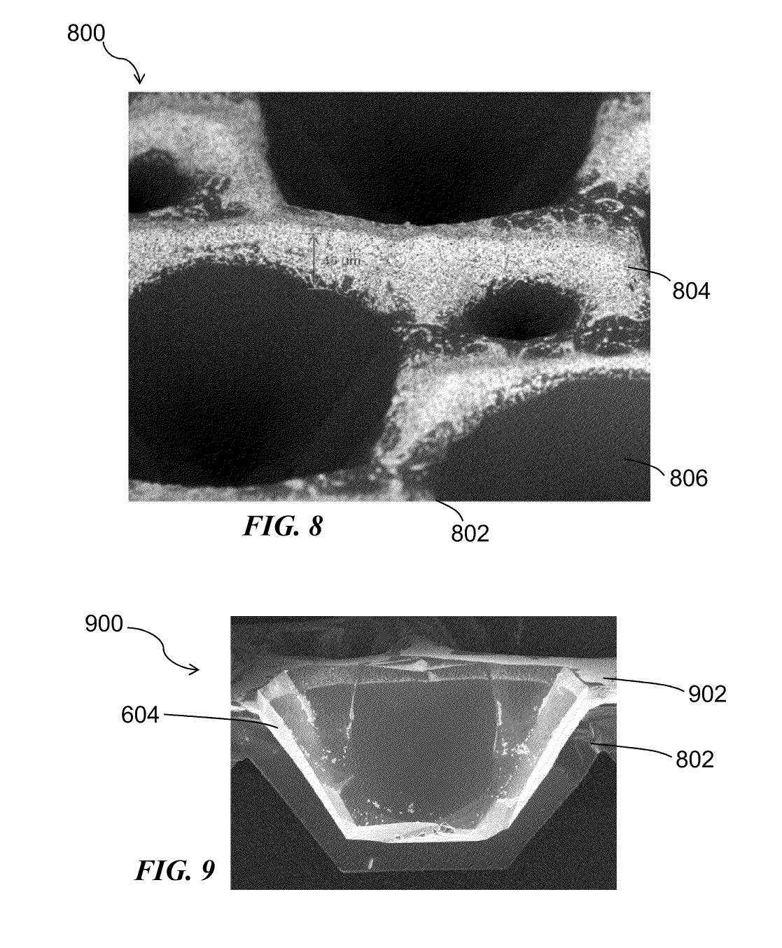

FIG. 8 shows an exemplary microscope view of a metal coated profile 800 of a honeycomb structure of a 3-D TFSS. The shown close-up view displays the ridge 802, the metal coating 804, and sidewall 806 of an exemplary honeycomb structure of a 3-D TFSS. The present disclosure teaches a method and apparatus for at least ninety percent continuous material coverage on the ridges, which is shown in the exemplary microscope view of a metal coated profile 800.

FIG. 9 illustrates a microscope view of a coated profile of pyramidal cell 900. A close-up view of a pyramidal cell 902 is shown in the microscope view of a coated profile of pyramid cell 900. The coated material 604 is on top of the ridge 802; however, limited, if any, coated material 604 is shown n the sidewalls of the pyramidal cell 902.

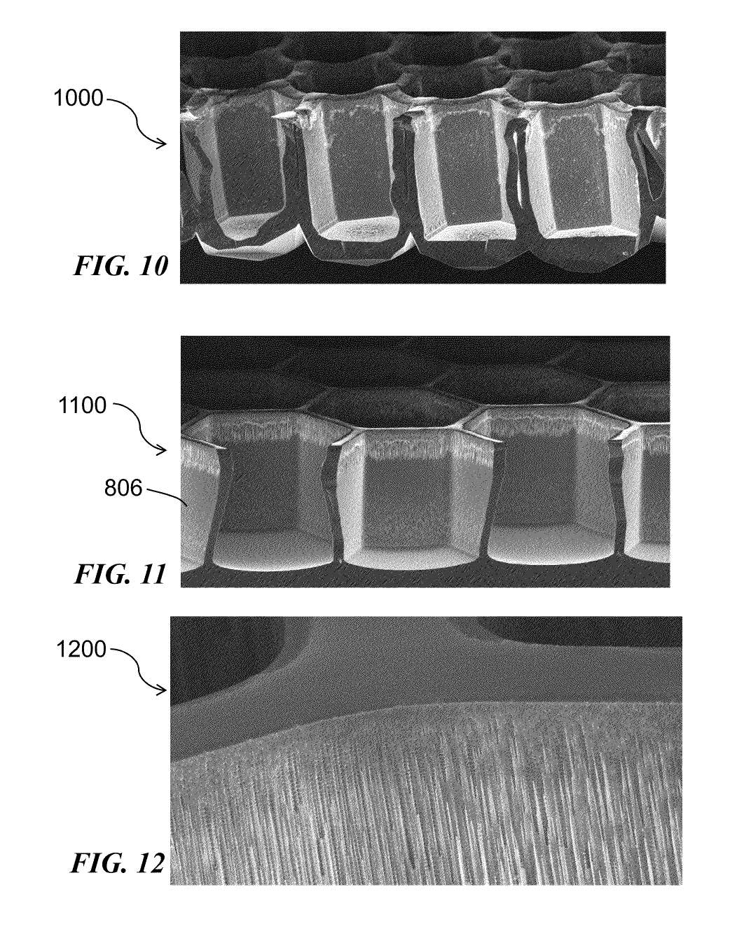

FIGS. 10, 11, and 12 presents additional microscope views of exemplary coated 3-D TFSSs. FIG. 10 presents a thicker coated profile along sidewall of honeycomb cell 1000. FIG. 10 shows a depiction of a wafer after application. One will note the good coverage obtained on top. This coverage may be obtained by pre-heating the wafer and then applying six coats of gel dopant using a soft roller. Between each coat, the wafer has a one minute vacuum bake at one hundred thirty-five degrees Celsius and then a final bake after all coats. The obtained coverage is more variable than the below example method and had a depth reaching as much as fifty to eighty microns.

FIG. 11 displays a thinner coated profile along sidewall of honeycomb cell 1100. FIG. 12 depicts a coated profile of the top ridge of a honeycomb cell 1200.

In summary, the present disclosure teaches a method and apparatus for transferring material on at least a portion of an uneven surface of a substrate in the manufacture of photovoltaic cells, which may include, but is not limited to a 3-D TFSS. An apparatus for transfer coating onto an uneven surface comprising an applicator roll, a transport roll, a heating device, a drying system, a conveying system, a reservoir, a blade, and a substrate. The present disclosure teaches a method for introducing a substrate onto a continuously conveying plane, selectively coating the material on an uneven surface, compressing the material to conform at the uneven surface, heating the material to a temperature more than that of the substrate, and drying the material to form continuous material coverage on said uneven surface. More particularly, a method and apparatus for passing the substrate in a controlled environment, agitating the material prior to step of selectively coating, and heating the conveying plane.

The detailed description set forth above in connection with the appended drawings is intended as a description of exemplary embodiments in which the presently disclosed process can be practiced. The detailed description includes specific details for providing a thorough understanding of the presently disclosed method and apparatus. However, it will be apparent to those skilled in the art that the presently disclosed process may be practiced without these specific details. In some instances, well-known structures and devices are shown in block diagram form in order to avoid obscuring the concepts of the presently disclosed methods and apparatus.

All references, including publications, patent applications, and patents, cited herein are hereby incorporated by reference to the same extent as if each reference were individually and specifically indicated to be incorporated by reference and were set forth in its entirety herein.

The detailed description set forth below in connection with the appended drawings is intended as a description of exemplary embodiments in which the presently disclosed process can be practiced. The term “exemplary” used throughout this description means “serving as an example, instance, or illustration,” and should not necessarily be construed as preferred or advantageous over other embodiments.

The detailed description includes specific details for providing a thorough understanding of the presently disclosed method and apparatus. However, it will be apparent to those skilled in the art that the presently disclosed process may be practiced without these specific details. In some instances, well-known structures and devices are shown in block diagram form in order to avoid obscuring the concepts of the presently disclosed method and system.

The foregoing description of the disclosed embodiments is provided to enable any person skilled in the art to make or use the claimed subject matter. Various modifications to these embodiments will be readily apparent to those skilled in the art, and the generic principles defined herein may be applied to other embodiments without the use of the innovative faculty. Thus, the claimed subject matter is not intended to be limited to the embodiments shown herein but is to be accorded the widest scope consistent with the principles and novel features disclosed herein. It is contemplated that additional embodiments are within the spirit and true scope of this disclosed method and system as claimed below.

What is claimed is:

1. A method for transferring material on at least a portion of an uneven surface of a substrate in the manufacture of photovoltaic cells and the like comprising steps of:
positioning said substrate;
selectively coating said material on said uneven surface;
compressing said material to conform at said uneven surface;
heating said material to a temperature more than that of said substrate; and
drying said material to form continuous material coverage on said uneven surface.

2. The method of claim 1, further comprising at least one of the additional steps of:
passing said substrate in a controlled environment;
agitating said material prior to step of selectively coating; and
heating said conveying plane.

3. The method of claim 1, wherein said uneven surfaces further comprises a plurality of ridges and wells, said ridges and said wells forming a three-dimensional structure, said three-dimensional structure further comprising sidewalls.

4. The method of claim 1, wherein said uneven surfaces are associated with the tips of any apertures less than or equal to four millimeters width in terms of the longest dimension.

5. The method of claim 1, wherein said ridges and said wells are associated with at least one of the following:
etching, microfabrication, micro-machining, micro-molding, drilling, laser ablation, or shadow-mask deposition.

6. The method of claim 1, wherein said material further comprises a thin film, said thin film providing at least eighty percentage coverage of said uneven surface.

7. The method of claim 1, wherein said material is associated with a viscosity value of no more than two hundred thousand.

8. The method of claim 1, wherein said continuous material coverage further comprises no more than one-hundred microns of film thickness.

9. The method of claim 1, wherein the step of selectively coating is associated with a thin film deposition technique, said thin film deposition technique associated with a chemical deposition or a physical deposition.

10. The method of claim 9, where said thin film deposition technique further comprises roll coating, said roll coating is associated with at least one of the following: an applicator roll, a transport roll, a conveyance plane, a cleaning blade, and a dosing roll.

11. The method of claim 1, wherein the step of selectively coating further comprises a thin film of no more than one-hundred microns of film thickness.

12. The method of claim 1, wherein the step of introducing is associated with a predetermined relative speed.

13. The method of claim 1, wherein said steps are repeated more than once.

14. An apparatus for transfer coating onto a substrate in the manufacture of photovoltaic cells comprising:
a substrate, said substrate further comprising uneven surfaces, said uneven surfaces further comprising a plurality of ridges and wells, said ridges and said wells forming a three-dimensional structure, said three-dimensional structure further comprising sidewalls;
a system of rollers, said system of rollers for selectively coating said material on said uneven surface;
a conveyance system, said conveyance system for introducing a substrate onto a continuously conveying plane;
a material, said material further comprises a thin film, said thin film providing at least ninety percentage coverage of said uneven surface.
a heating device, said heating device for heating said material to a temperature more than that of said substrate; and
a drying system, said drying system forming a continuous material coverage on said uneven surface.

15. The apparatus of claim 14, wherein said system of rollers passes said substrate in a controlled environment.

16. The apparatus of claim 14, wherein said system of rollers agitates said material while selectively coating.

17. The apparatus of claim 14, wherein said systems of rollers further comprises an applicator roll, said applicator roll for compressing said material to conform at said uneven surface;

18. The apparatus of claim 14, wherein said heating device promotes thinning of said material, said thinning associated with a reduction in viscosity.

19. The apparatus of claim 14, wherein said applicator roll further comprises a smooth surface or a textured surface.

20. The apparatus of claim 14, wherein said heating device is associated with applying heat to said system of rollers.
